(19) United States
(12) Patent Application Publication
(10) Pub. No.: US 2009/0311512 A1
(43) Pub. Date: Dec. 17, 2009

(54) Radiation-Emitting Component

(75) Inventors: Hans Braun, Grevenbroich (DE); Markus Klein, Tegernheim (DE); Klaus Meyer, Dormagen (DE); Ralph Pätzold, Roth (DE); Heinz Pudleiner, Krefeld (DE); Wiebke Sarfert, Herzogenaurach (DE); Florian Schindler, Traunstein (DE)

Correspondence Address: COHEN, PONTANI, LIEBERMAN & PAVANE LLP, 551 FIFTH AVENUE, SUITE 1210, NEW YORK, NY, 10176, US

(73) Assignees: OSRAM Opto Semiconductors GmbH, Regensburg (DE); Bayer Material Science AG, Leverkusen (DE)

(21) Appl. No.: 12/375,875

(22) PCT Filed: Jul. 4, 2007
(86) PCT No.: PCT/DE07/01180

§ 371 Date: Aug. 12, 2009

(30) Foreign Application Priority Data
Jul. 31, 2006 (DE) 102006035628.4
Dec. 14, 2006 (DE) 102006059129.1

(51) Int. Cl. B32B 5/16; B32B 9/04; B32B 27/36; B32B 5/00; H01L 51/52

(52) U.S. Cl. 428/323; 428/411.1; 428/412; 428/339

(57) ABSTRACT

An organic radiation-emitting component (1) comprising an organic layer (2) formed for generating radiation, and comprising a radiation coupling-out side is specified, a scattering film (8) being arranged on the radiation coupling-out side of the component and being connected to the component.

The present invention relates to a radiation-emitting component, in particular an optoelectronic component.

This patent application claims the priority of German Patent Applications 10 2006 035 628.4 of 31 Jul. 2006 and 10 2006 059 129.1 of 14 Dec. 2006, the entire disclosure content of which is hereby explicitly incorporated by reference in the present application.

The application WO 2005/018010 describes organic electroluminescent products having improved light extraction, which have a light-scattering medium arranged in adjacent fashion.

The application EP 1 406 474 describes a light extraction OLED device comprising

(a) a transparent substrate;

(b) a light scattering layer arranged above a first surface of the transparent substrate;

(c) a transparent first electrode layer arranged above the light scattering layer;

(d) an organic EL element arranged above the transparent first electrode layer, the electrode layer comprising one or a plurality of organic layers, but at least one luminous layer in which light is generated;

(e) a transparent second electrode layer arranged above the organic EL element;

(f) a reflector layer arranged above the transparent second electrode layer;

(g) an insulation layer having a low index, the optical index of which is less than that of the luminous layer arranged between the transparent second electrode and the reflector layer.

It is an object of the present invention to specify an improved component. In particular, the intention is to specify a radiation-emitting component which is improved with respect to the coupling-out efficiency and/or the homogeneity of the radiation power distribution on the coupling-out side.

This object is achieved by means of a radiation-emitting component comprising the features of Patent Claim 1. The dependent patent claims relate to advantageous configurations and developments of the invention.

A radiation-emitting component according to the invention comprises an active layer formed for generating radiation, and comprises a radiation coupling-out side. A scattering film is arranged on the radiation coupling-out side and is connected to the component.

Preferably, the component is formed as an organic radiation-emitting component, in particular as an organic light-emitting diode (OLED). In this case, the active layer is expediently formed by means of an organic layer containing an organic (semi)conducting material. In this case, the organic layer contains for example at least one (semi)conducting polymer and/or comprises at least one layer with a (semi)conducting molecule, in particular a low-molecular-weight molecule.

Radiation generated in the component can be scattered by means of the scattering film. By this means, a more homogeneous distribution of the radiation power by comparison with a corresponding component without a scattering film on the part of the radiation coupling-out side of the component can be obtained. Moreover, the beam course can be disturbed by scattering events at or in the scattering film. This advantageously leads to an increase in the radiation power coupled out during operation of the component. In particular, an undesirable wave guiding in the component, which can occur for example on account of (multiple) reflection, in particular total reflection, in the component, can be disturbed and the radiation power coupled out from the component can be advantageously increased by this means.

Furthermore, the scattering film is preferably applied to an already prefabricated, functional component and is fixed to the component. Accordingly, it is not necessary, in particular, for all the components of a production batch to be equipped with a scattering film. Rather, in an application-specific manner, merely selected components can be provided with a scattering film. By comparison with a scattering element that is integrated in the component during the production thereof, the subsequent equipping of components with the scattering film affords the advantage that the latter can be provided as necessary.

By way of example, already prefabricated components can firstly be tested with regard to a criterion, for example regarding the functionality of the component, the colour locus of the radiation generated or a minimum desired value of the coupled-out radiation power. Afterwards, only those components which meet the criterion can be provided with a scattering film. The production costs of a composite component comprising component and scattering film, which has an advantageously increased coupled-out efficiency, can be advantageously reduced as a result since defective components can be separated out and not be provided with the scattering film.

A prefabricated OLED can comprise, in particular, electrodes for making electrical contact and, as an alternative or in addition, an encapsulation that protects the organic layer, which encapsulation protects the organic layer against moisture, for example.

In an advantageous configuration, the scattering film is formed as a transmission scattering film which scatters radiation generated in the active layer, in particular, and passing through the scattering film. By comparison with a reflection scattering film which reflects scattered radiation back into the component, a transmission scattering film affords the advantage that beam deflection and absorption in the component are avoided. A surface of the scattering film that is remote from the component can be formed as an area for coupling out radiation from the composite component comprising the component and the scattering film.

In an advantageous configuration, the component comprises a substrate, on which the active layer is arranged. By way of example, the active layer can be applied on the substrate during the production of the component. Expediently, the substrate mechanically stabilizes the active layer.

The substrate can be formed in particular by a layer on which the organic layer and, if appropriate, electrodes for making electrical contact and/or further elements of the component are applied.

The scattering film is preferably arranged on that side of the substrate which is remote from the active layer and is connected to the substrate. On account of the generally high mechanical stability of the substrate by comparison with the film, the scattering film can be fixed to the substrate stably and preferably permanently in a particularly simple manner. Expediently, the substrate is formed in self-supporting fashion.

As an alternative, the substrate can be formed in a flexible fashion. By way of example, a film, in particular a plastic film, e.g. a PMMA film, is suitable for a flexible embodiment. By means of the scattering film, the mechanical stability of the substrate/scattering film composite can be increased by comparison with a flexible substrate that is not provided with a scattering film.

Preferably, the substrate is formed such that it is transmissive to radiation generated in the active layer, and in particular is formed from a radiation-transmissive material That side of the substrate which is remote from the active layer can form a radiation exit area of the component. By way of example, the substrate contains a glass. A glass substrate is often used particularly in OLEDs.

In conventional components without a scattering film, generally a considerable proportion of radiation that has entered into the substrate is subjected to continuous wave guiding in the substrate. This may be (concomitantly) caused by total reflection at that surface of the substrate which is remote from the active layer. Radiation continually reflected in the substrate can exit from a non-desirable area of the substrate, e.g. a lateral area. The radiation power that can be coupled out via that surface of the substrate which is remote from the active layer and which can be provided as main exit area of the component is undesirably reduced by this means.

Furthermore, radiation reflected at that surface of the substrate which is remote from the active layer can be absorbed again in the component. The absorbed proportion is then naturally no longer available for coupling out.

Both the proportion of radiation that is reflected back at the substrate and the wave guiding in the substrate can be advantageously reduced by means of scattering at or in the scattering film. The coupling-out efficiency of the component is consequently increased.

The substrate can furthermore be formed in electrically insulating fashion. In this case, electrical contact is made with the component preferably on that side of the substrate which is remote from the scattering film.

The substrate can furthermore be provided with the scattering film essentially over the whole area. Preferably, the scattering film completely covers at least the active layer.

In a further advantageous configuration, the scattering film comprises a film matrix admixed with local scattering zones. The scattering zones preferably have a refractive index that is different from that of the matrix material of the film matrix. The expediently radiation-transmissive matrix material can be equipped with scattering properties for the scattering film by formation of the refractive index inhomogeneities.

The refractive index of the scattering zones deviates from the refractive index of the matrix material preferably by 0.6% or more, particularly preferably by 3.0% or more, and particularly advantageously by 6% or more. The greater the deviation, the more efficient generally is the scattering by means of the scattering zone.

Preferably, the scattering zones are formed such that they are radiation-transmissive to the radiation generated in the active layer. Accordingly, the scattering of radiation can be effected in the scattering film by refraction upon entering into, upon passing through and/or upon exiting from the scattering zones.

In a further preferred configuration, the scattering film or the film matrix contains a plastic that is transmissive to the radiation generated in the active layer, e.g. a thermoplastic.

All transparent thermoplastics can be used as plastics for the films: polyacrylates, polymethyl methacrylates (PMMA; Plexiglas® from Röhm), cycloolefin copolymers (COC; Topas® from Ticona); Zenoex® from Nippon Zeon or Apel® from Japan Synthetic Rubber), polysulphones (Ultrason® from BASF or Udel® from Solvay), polyesters, such as e.g. PET or PEN, polycarbonate, polycarbonate/polyester blends, e.g. PC/PET, polycarbonate/polycyclohexylmethanol cyclohexane dicarboxylate (PCCD; Xylecs® from GE) and polycarbonate/polybutylene terephthalate (PBT) blends.

By way of example, the scattering film or the film matrix contains a polymer, for instance a polycarbonate. Plastic films, in particular polycarbonate-based films, can be manufactured simply and cost-effectively.

In a further advantageous configuration, the scattering zones comprise, in particular radiation-transmissive, scattering particles. By means of scattering particles added to the matrix material, well-defined local scattering zones can be formed in a particularly simple manner. The scattering particles preferably comprise inorganic or organic particles, particularly preferably organic particles. Plastic particles and/or polymer particles are particularly well suited as scattering particles.

By means of the scattering particles, the beam course of (light) beams in the film can be deflected from the original direction—that is to say the direction prior to the scattering event at a scattering particle.

In an advantageous development, the scattering particles comprise hollow particles, in particular polymeric hollow particles. By means of the cavity of the hollow particles, refractive index inhomogeneities in the matrix material can be formed. The interior of the hollow body can be for example gas-filled, e.g. air-filled.

By means of polymer hollow particles, particularly high refractive index differences can be obtained in a polymer matrix provided with the polymer hollow particles. Radiation-transmissive polymeric materials generally have refractive indices that deviate comparatively little from one another.

By contrast, the polymer-free interior of the hollow body may exhibit an increased refractive index deviation with respect to the matrix material in a simplified manner by comparison therewith.

Such hollow spheres are described e.g. in U.S. Pat. No. 5,053,436. The wall material comprises acrylate polymer and the interior is filled with ambient air.

In a further advantageous development, the scattering particles comprise particles with a core-shell construction, in particular polymer particles having a core-shell morphology. These particles are preferably embodied as solid particles and not as hollow particles.

Since the particle core is spaced apart from the matrix material by the particle shell enveloping the core, a material which would be suitable only to a limited extent or even unsuitable for direct contact with the matrix material can also advantageously be used for the particle core. By way of example, a core material which would promote the degradation of polymer chains of the matrix material and would accordingly not be suitable if it were not spaced apart from the matrix material can be used. The construction as core-shell particles comes from the application as impact modifiers. Rubber-elastic particles (core of the particles) are actually required for this purpose, which particles are particularly immiscible and incompatible, however, with most thermoplastics. That leads to poor mechanical properties of the mixtures. In order to improve the (mixing) compatibility of the rubber particles, they can be “coated” with an envelope, e.g. an acrylate envelope. The envelope can be applied by polymerization, e.g. by changing the monomers. The envelope then surrounds the particle core and the envelope forms the shell.

In a further preferred configuration, the scattering zones, in particular the scattering particles, have an average diameter (average zone diameter or size) of at least 0.5 μm. preferably of at least 1 μm up to 100 μm or even up to 120 μm, more preferably of 2 to 50 μm, most preferably of 2 μm to 30 μm. “Average diameter” (average zone diameter) should be understood to mean the number average. Preferably at least 90%, most preferably at least 95% of the scattering zones have a diameter of more than 1 μm and less than 100 μm. Such dimensions for the scattering zones and in particular the scattering particles impart particularly good diffusive properties to the scattering film, in particular for the scattering of visible light.

For an OLED, diameters in the above sense of between 0.5 μm and 50 μm inclusive, preferably between 2 μm and 30 μm inclusive, have proved to be particularly suitable.

In a further preferred configuration, a scattering structure, which is in particular irregular and preferably formed statistically, is formed in a surface of the scattering film. By means of scattering of radiation at the surface, it is possible, on account of the disturbed reflection at said surface, on the one hand to increase the radiation power that can be coupled out from the scattering film and, on the other hand, on account of diffusive scattering, to improve the homogeneity of the radiation power distribution on the part of the coupling-out area of the scattering film. The scattering structure is expediently formed in that surface of the scattering film which is remote from the component, in particular from the substrate.

In a further advantageous configuration, a roughness of the scattering film, in particular the roughness of the surface with the scattering structure, is greater than 3 μm, preferably greater than 4 μm. The roughness is furthermore preferably less than 300 μm, particularly preferably less than 50 μm. The roughness can be determined according to ISO 4288.

The structured surface of the scattering film preferably has a degree of gloss of less than 50%, preferably of less than 40%. Furthermore, the degree of gloss is preferably greater than 0.5%. The degree of gloss can be determined according to EN ISO 2813 (angle 60°).

In a further configuration, the scattering film can also have a glossy surface. The latter is expediently embodied in unstructured fashion. In this case, the glossy surface is preferably formed by means of that surface of the scattering film which faces the component. Said surface preferably has a degree of gloss of more than 50%.

Particularly advantageously, the scattering structure is provided in addition to the scattering zones. Thereby, the coupling out from the composite component can be increased to a particularly great extent—by volume scattering at the scattering zones and surface scattering at the scattering structure, and at the same time a particularly homogeneous radiation power distribution on the exit side of the composite component can be obtained.

Furthermore, the optical impression of the composite component, e.g. rather matt or rather glossy, can be set by way of the type of structuring of the structured surface.

In a further preferred configuration, the scattering film or the film matrix is refractive-index-matched to the component. The radiation transfer of radiation from the component into the scattering film is thus facilitated and the reflection losses at interface(s) between component and scattering film are reduced. For the refractive index matching, the refractive index of the scattering film or, for the case where scattering zones are formed, that of the matrix material deviates from the refractive index of the material arranged on the part of the component, in particular the refractive index of the substrate, preferably by 20% or less, particularly preferably by 10% or less.

For the refractive index matching, it is possible to use a correspondingly suitable material for the film. For refractive index matching to a glass substrate, by way of example, a polycarbonate is particularly suitable for the film.

As an alternative or supplementarily, a refractive index matching material, e.g. an optical gel for the refractive index matching, can be used, which is arranged between the scattering film and the substrate. The refractive index matching material preferably reduces the refractive index jump from the substrate to the scattering film.

In a further advantageous configuration, the scattering film is fixed to the component. Preferably, the scattering film is fixed to the component, in particular the substrate, by means of an adhesive promoter or the scattering film is laminated onto the component, in particular onto the substrate. If an adhesion promoter is used, then it can advantageously simultaneously serve as refractive index matching material.

In a further advantageous configuration, the scattering film has a thickness of between 1 μm and 1 mm inclusive, preferably between 25 μm and 500 μm inclusive, particularly preferably between 25 μm and 300 μm inclusive. The thickness of the film can be greater than or equal to 30 μm.

In case of doubt, a film should be regarded as a layer or a layer composite which does not carry its own weight, that is to say is formed such that it is not self-supporting, and in particular is flexible.

As an alternative, in the context of the invention, a scattering layer, e.g. having a thickness of up to 10 mm, can also be used, which possibly no longer has film character. A scattering layer having film character is particularly suitable, however, in particular on account of flexibility.

In a further preferred configuration, the composite substrate comprising the scattering film and the substrate is mechanically stabilized on account of the scattering film in such a way that the composite substrate is mechanically stabilized by the scattering film even in the event of damage to the substrate.

This is particularly expedient if the substrate is formed from a fragmentable material, for example glass. A fragmented substrate can be held together by means of the scattering film. For this purpose, the scattering film is expediently formed with a suitable mechanical stability and is connected to the substrate mechanically stably and preferably permanently.

By means of the scattering film, the overall stability of the composite substrate and in addition that of the composite component can thus advantageously be increased. Furthermore, the risk of injuries caused by fragments when handling the component is reduced.

In a further preferred configuration, the scattering film is embodied as a layer composite having a plurality of individual layers. Preferably, the scattering film is embodied as a (co)extruded layer composite.

In a further advantageous configuration, an ultraviolet-radiation—(UV)-absorbing element is connected to the component. The element is preferably arranged on that side of the substrate which is remote from the active layer.

In a first advantageous development, the element is embodied as a separate UV protective film which absorbs ultraviolet radiation. The separate UV protective film can be provided in a film composite with the scattering film. The two films can be embodied in particular in coextruded fashion for a film composite.

In a further advantageous development, the scattering film is formed such that it is UV-absorbent, for example by addition of one or a plurality of additives. As an alternative or supplementarily, a UV-absorbent material can be used for the film matrix.

Both the base layer of the film composite, in particular the layer with the scattering particles, and the optionally present coextrusion layer(s) of the films according to the invention can additionally contain additives, such as, for example, UV absorbers and/or other processing aids. This encompasses in particular mould release agents, flow agents, stabilizers customary for polycarbonates, in particular thermostabilizers, antistatic agents and/or optical brighteners. In this case, different additives or different concentrations of additives may be present in each layer. Preferably, the coextrusion layer(s) contains (contain) the antistatic agents, UV absorbers and/or mould release agents.

In one preferred embodiment, the composition of the film additionally contains 0.01 to 0.5% by weight of a UV absorber from the classes of benzotriazole derivatives, dimeric benzotriazole derivatives, triazine derivatives, dimeric triazine derivatives, diaryl cyanoacrylates.

Particularly in OLEDs, ultraviolet radiation can damage the organic layer provided for generating radiation and bring about a component defect in accelerated fashion. This UV ageing can be at least inhibited by means of the ultraviolet-radiation-absorbing element.

In a further advantageous configuration, the component is provided for lighting, in particular for general lighting. By comparison with a use in displays, in which it is necessary to preserve the selectivity between individual pixels, a scattering film that would cause blurring of the individual pixels in displays can be used without a significant disadvantageous effect in components for general lighting.

The component can be used for example for interior lighting, for exterior lighting or in a signal luminaire.

The component, in particular for use in general lighting, is preferably formed for generating visible radiation. The luminance on the coupling-out side can be considerably increased by means of the scattering film.

In a further preferred configuration, an element having an antistatic effect, in particular on the part of the radiation coupling-out side, is connected to the component. Dirt deposits at the (composite) component can be reduced by this means. It has proved to be particularly advantageous to form the scattering film in antistatic fashion. Electrostatically caused deposits at the film which can adversely affect the radiation power distribution on the exit side are thus reduced. An antistatic agent can advantageously be integrated in the scattering film.

As an alternative, the element having an antistatic effect can be provided as a separate antistatic film in a film composite that is coextruded in particular jointly with the scattering film.

Examples of suitable antistatic agents are cationic compounds, for example quaternary ammonium, phosphonium or sulphonium salts, anionic compounds, for example alkylsulphonates, alkyl sulphates, alkyl phosphates, carboxylates in the form of alkali or alkaline earth metal salts, non-ionic compounds, for example polyethylene glycol esters, polyethylene glycol ethers, fatty acid esters, ethoxylated fatty amines. Preferred antistatic agents are quaternary ammonium compounds, such as e.g. dimethyldiisopropylammonium perfluorobutanesulphonate.

Overall, a scattering film for a coupling-out layer of a radiation-emitting component and in particular also the use of a scattering film in a radiation-emitting component affords a multiplicity of advantages that are set out above and below.

Further features, advantages and expediencies of the invention emerge from the following description of the exemplary embodiments in conjunction with the figures.

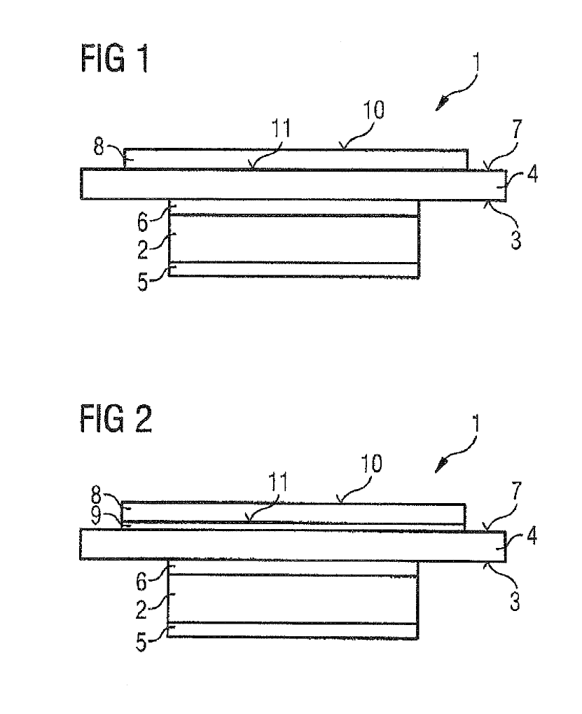

FIG. 1 shows an exemplary embodiment of a radiation-emitting component according to the invention on the basis of a schematic sectional view.

FIG. 2 shows a further exemplary embodiment of a radiation-emitting component according to the invention on the basis of a schematic sectional view.

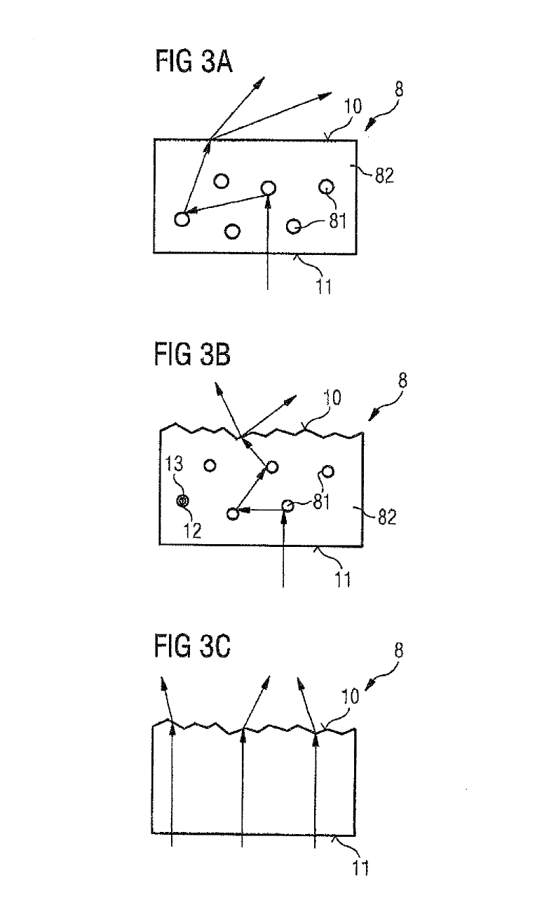

FIG. 3 shows, on the basis of FIGS. 3A, 3B and 3C, in each case an exemplary embodiment of a scattering film for a component according to the invention.

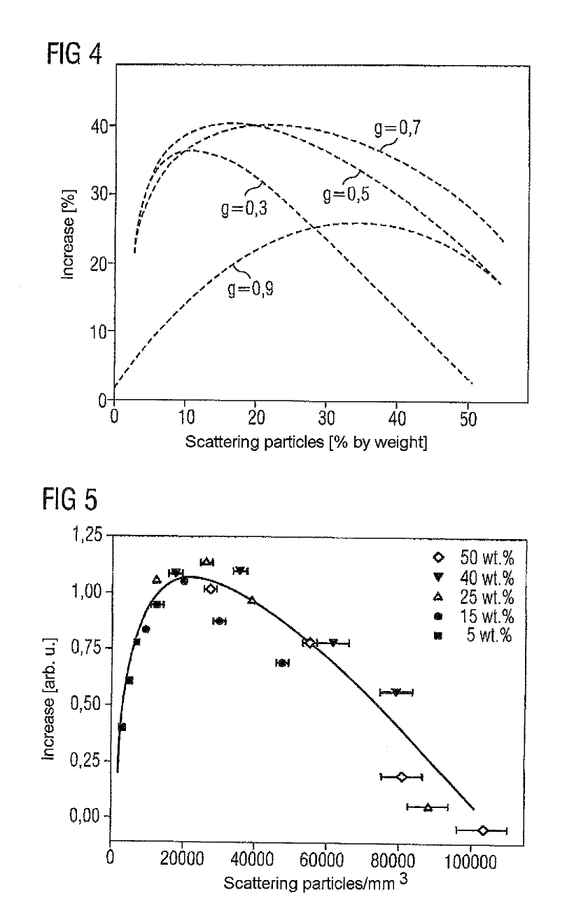

FIG. 4 shows the results of a simulation calculation for the dependence of the increase in coupled-out radiation power on the weight concentration of scattering particles.

FIG. 5 shows measurement results for the dependence of the increase in coupled-out radiation power on the number of scattering particles.

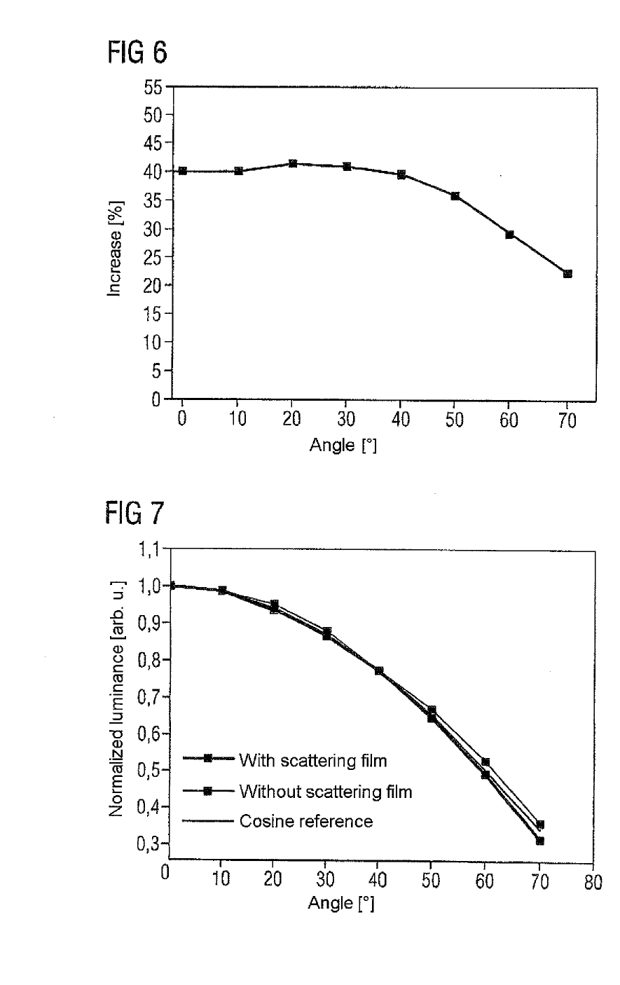

FIG. 6 shows the dependence of the increase in coupled-out radiation power on the viewing angle for a component according to the invention.

FIG. 7 shows the emission characteristics of a component according to the invention, of a component without a scattering film, and the cosinusoidal emission characteristic of a Lambertian emitter.

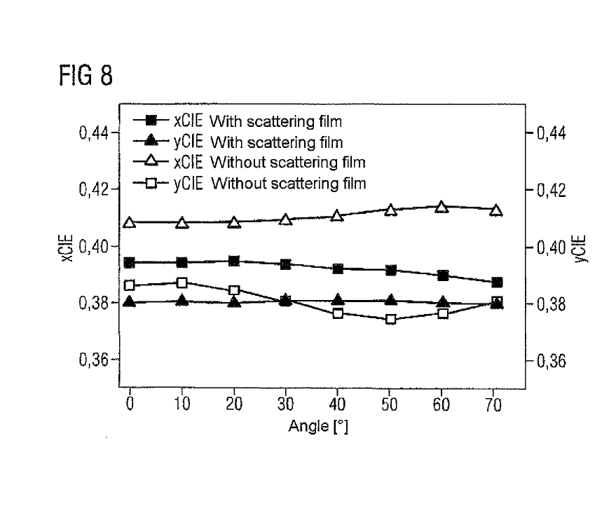

FIG. 8 shows the dependence of the CTE colour coordinates x and y on the viewing angle for a component with a scattering film and a component without a scattering film.

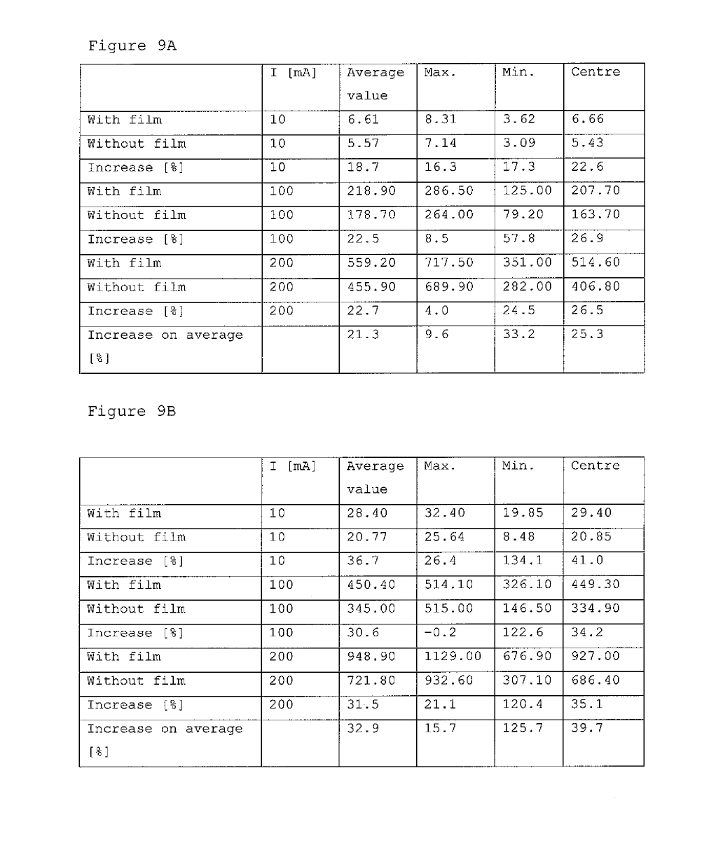

FIG. 9 shows, on the basis of the tables in FIGS. 9A and 9B, measured and average values determined for different operating currents and also the increase in radiation power determined therefrom.

Elements that are identical, of identical type and act identically are provided with identical reference symbols in the figures.

FIGS. 1 and 2 in each case show an exemplary embodiment of a radiation-emitting component according to the invention on the basis of a schematic sectional view.

The radiation-emitting component 1 is in each case embodied as an OLED. The component 1 comprises an organic layer 2 formed for generating radiation, or a corresponding layer stack having a plurality of organic layers. The organic layer 2 is arranged on a first main area 3 of a substrate 4 of the radiation-emitting component and is connected thereto.

For charge carrier injection into the organic layer 2, the latter is electrically conductively connected to a first electrode 5, e.g. the cathode, and a second electrode 6, e.g. the anode. Via said electrodes 5, 6, the organic layer can be fed charge carriers—electrons and holes—for generating radiation by recombination in the organic layer 2. The electrodes 5 and 6 are preferably formed in layered fashion, the organic layer particularly preferably being arranged between the electrodes. The electrodes and the organic layer 2 can be applied to the first main area 3 of the substrate.

The organic layer or the organic layers preferably contains or contain a semiconducting organic material.

By way of example, the organic layer contains a semiconducting polymer. Suitable organic or organometallic polymers include: polyfluorenes, polythiopenes, polyphenylenes, polythiophenevinylenes, poly-p-phenylenevinylenes, polyspiro polymers and their families, copolymers, derivatives and mixtures thereof.

As an alternative or supplementarily to polymer materials, the organic layer can contain a low-molecular-weight material (so-called small molecules). Suitable materials having a low molecular weight (low-molecular-weight materials) are for example tris-8-aluminium-quinolinol complexes, Irppy (tris(2-phenylpyrridyl)iridium complexes) and/or DPVBI (4,4′-bis(2,2-diphenyl-ethen-1-yl)diphenyl) complexes.

The substrate 4 is formed such that it is radiation-transmissive to radiation generated in the organic layer 2. Preferably visible light is generated by means of the organic layer 2. By way of example, the radiation-transmissive substrate used is a glass substrate, for example composed of Borofloat glass, or a plastic (film) substrate, e.g. composed of PMMA (poly(methyl methacrylate)).

Light passing through the second main area 7 of the substrate 4, said second main area being remote from the organic layer 2, can couple out from the component 1. In particular, the radiation exit area of the component can be formed by means of the second main area 7. A mirror layer can furthermore be arranged on that side of the organic layer 2 which is remote from the substrate 4. Said mirror layer reflects radiation directed away from the substrate in the organic layer preferably back in the direction of the substrate 4. The radiation power emerging via the radiation exit area during operation of the component can thus be increased. Preferably, the first electrode 5 is formed as a reflective electrode and hence simultaneously as a mirror layer. For this purpose, the electrode 5 is preferably embodied in metallic fashion or in an alloy-based fashion. A separate mirror layer is not explicitly shown in the figures.

The electrode 5 may, if appropriate, be embodied as a multilayer structure. Preferably, one of the layers is formed for the charge carrier injection into the organic layer 2 and a further layer of the electrode is formed as a mirror layer. The layer for the charge carrier injection is expediently arranged between the mirror layer and the organic layer. The mirror layer and/or the charge carrier injection layer can contain or comprise a metal, e.g. Au, Al, Ag or Pt, the two layers expediently containing different metals.

If appropriate, an alloy, preferably with at least one of the abovementioned metals, is also suitable for the (multilayer) electrode 5.

The second electrode 6 is arranged between the substrate 4 and the organic layer 2. For the passage of radiation, said electrode is expediently formed such that it is radiation-transmissive. By way of example, the electrode contains an indium tin oxide (ITO) for this purpose,

On the radiation coupling-out side of the component 1, that is to say that side of the substrate 4 which is remote from the organic layer 2, a scattering film 8 is fixed to the substrate.

The illustration of an encapsulation for the organic layer 2, which is preferably arranged on that side of the substrate 4 which is remote from the scattering film 8, has been dispensed with for reasons of clarity. Such an encapsulation encapsulates the organic layer against harmful external influences, such as moisture. The encapsulation may be formed e.g. as a roof construction.

An explicit illustration of the electrical contact-connection of the component has also been dispensed with. Thus, e.g. a drive circuit of the component may be arranged on the substrate—if appropriate within the encapsulation.

The component may also comprise, if appropriate, a plurality of, preferably structured, mutually separate organic layers or layer stacks. The different layers or layer stacks may be formed for generating varicoloured light, e.g. red, green and blue light.

In the exemplary embodiment in accordance with FIG. 1, the scattering film 8 is laminated onto the second main area of the substrate 4, whereas in the exemplary embodiment in accordance with FIG. 2, a separate adhesion promoting layer 9, for example an adhesive layer, is provided, by means of which the scattering film is fixed to the substrate 4. By way of example, a Norland Optical Adhesive, for instance the one with the type designation LOT No. 68, is suitable as adhesion promoter.

The scattering film 8 is formed as a transmission scattering film, such that radiation passing into the scattering film from the substrate 4 is scattered by means of the scattering film and emerges from the scattering film as scattered radiation via the surface 10 of the scattering film, said surface being remote from the substrate.

By means of the scattering film, it is possible to increase the radiation power coupled out during operation from the composite component illustrated in FIGS. 1 and 2, said composite component comprising, alongside the component, the scattering film fixed thereto.

By means of scattering events in the film and/or scattering at the film surface, the beam course in the film can be disturbed, in comparison with a coupling-out layer that is not formed for scattering, by means of statistical beam deflections by comparison with the regular course. In particular, the impingement angles of radiation on that surface of the scattering film which is remote from the organic layer 2 can be distributed randomly and in particular more widely. The proportion of radiation reflected back at the surface 10 of the film that is remote from the organic layer 2 can be reduced by means of the scattering. The proportion of radiation that is coupled out via the surface 10 of the scattering film is accordingly advantageously increased. The scattering film serves in particular as the coupling-out layer of the composite component.

Furthermore, the radiation power distribution on the radiation coupling-out side of the composite component can be homogenized in a simple manner by means of the scattering film. In particular, a defective region of the organic layer, which region would appear as a dark region in the absence of the scattering film on the coupling-out side, can be compensated for by way of diffusive light scattering by means of the scattering film.

A scattering film 8 can be fixed to the respective components that have been found to be suitable after a multiplicity of components have been tested, for instance with regard to functionality or a sufficient radiation power, and unsuitable components have been sorted out. In contrast to a scattering element that is integrated in the respective components as early as during fabrication, the production costs can thus be decreased on account of the reduced rejects.

The component 1 is preferably formed for lighting, in particular for general lighting. By comparison with a use in displays, in which it is necessary to preserve the selectivity between individual pixels, a scattering film that would cause blurring of the individual pixels in displays can be used without a significant disadvantageous effect in components for general lighting.

The component can be used for example for interior lighting, for exterior lighting or in a signal luminaire.

The component, in particular for use in general lighting, is expediently formed for generating visible radiation. The luminance on the coupling-out side, the specific light emission on the coupling-out side and/or the brightness on the coupling-out side can be considerably increased by means of the scattering film.

FIGS. 3A, 3B and 3C in each case show an exemplary embodiment of a scattering film 8. These scattering films can be used in the components in accordance with FIGS. 1 and 2.

In the exemplary embodiments in accordance with FIGS. 3A and 3B, the scattering film 8 comprises a film matrix 82 admixed with scattering particles 81. The film matrix 82 is preferably formed from a radiation-transmissive plastic, for example polycarbonate. Organic plastic particles, in particular, are suitable for the scattering particles. The scattering particles are preferably embodied as polymer particles.

Furthermore, the scattering particles 81 are preferably embodied such that they are radiation-transmissive. For a scattering effect, the scattering particles expediently have a refractive index that differs from the refractive index of the film matrix material. With radiation-transmissive scattering particles, a scattering effect can accordingly be effected by reflection at the interface with the film matrix and/or refraction upon entering into, upon passing through and/or upon exiting from the scattering particle.

The scattering particles can be admixed with a moulding compound for the film matrix prior to the production of the film in a statistical distribution. The proportion of scattering particles in the scattering film is preferably 50 per cent by weight or less.

In the case of the films illustrated in FIGS. 3A and 3B a volume scattering process accordingly takes place at the particles in the film volume.

The refractive index of the scattering particles deviates from the refractive index of the matrix material preferably by

0.6% or more, particularly preferably by

3.0% or more and particularly advantageously by 6% or more. The greater the deviation, the more efficient generally is the beam deflection by means of the scattering particles.

By way of example, polymer hollow particles are suitable for the scattering particles, scattering being effected by refraction in this case principally on account of the comparatively high refractive index difference between hollow body interior and hollow body wall. If polymeric materials are used both for the film matrix 82 and for the surrounding wall of the cavity of the hollow particle, then these generally have a comparatively small refractive index difference. The refractive index difference between the material of the surrounding wall and the interior, which can be filled for example with gas, for instance air, can be made larger in a simplified manner by comparison therewith. Such a polymeric hollow particle with the gas-filled cavity 12 and the cavity wall 13 is indicated schematically in FIG. 3B.

In a departure from the hollow particles described above, of course, radiation-transmissive solid particles, in particular polymer particles, which are essentially free of cavities, can also be used. Polymer particles preferably have a core-shell morphology. In the illustration in FIG. 3B, the reference symbol 12 would then correspond to the core, and the reference symbol 13 to the shell.

In addition to the scattering particles 81, the surface 10 of the scattering film 8 shown in FIG. 3B, said surface being remote from the component, is provided with a scattering structure. By means of the scattering structure, scattering can also be effected at the surface of the film in addition to the volume scattering at the particles. For the scattering structure, an irregular structure of the surface is particularly suitable, in particular a structure according to a statistical pattern.

Furthermore, the optical impression of the component in the switched-off state can be set by means of the surface structuring of the surface 10 of the scattering film 8 that is remote from the substrate 4. The component can appear to be more glossy or rather matt, depending on the type of surface structuring.

FIG. 3C shows a scattering film 8 which has a scattering structure but is not admixed with scattering particles 81. This scattering film therefore has only a surface structuring. With regard to the use of the volume of the film for scattering, the use of scattering particles is preferred. However, the radiation power coupled out from the component can also already be increased with a scattering film that only has a structured surface.

The arrows in FIGS. 3A to 3C symbolize beam paths in the scattering film 8 by way of example, in which case an illustration of radiation passage through the particles has been dispensed with for reasons of clarity in the case of the films provided with scattering particles 81 in accordance with FIGS. 3A and 3B.

The scattering film 8 preferably has a thickness of between 25 μm and 500 μm, particularly preferably between 25 μm and 300 μm. These thicknesses are particularly suitable on the one hand with regard to the scattering effect, and on the other hand with regard to increasing the overall mechanical stability of the composite component. In particular, by means of a scattering film subsequently fixed to a prefabricated component, the stability of the component can remain ensured even in the case of a shattered glass substrate. Moreover, the risk of injury due to fragments can be reduced on account of the fragmentation protective scattering film.

For efficient scattering, the roughness of the structured surface 10 is greater than 3 μm, preferably greater than 4 μm and less than 300 μm, particularly preferably greater than 4 μm and less than 50 μm.

On account of the both volume- and surface-scattering properties, a scattering film in accordance with FIG. 3B is particularly suitable for increasing the coupled-out radiation power. By means of a scattering film of this type, it was possible to obtain an increase in the luminance by more than 20% by comparison with a component of identical type without a scattering film.

For optimized coupling of radiation from the component 1 into the scattering film 8, the surface 11 of the scattering film that faces the component is expediently formed in planar and in particular unstructured fashion. If appropriate, a scattering film with a structured surface 11 can be used.

In order to facilitate the radiation transfer from the substrate 4 into the scattering film 8, the matrix material in the case of a scattering film provided with scattering particles, and the material of the film in the case of a scattering film having only a surface structuring, is expediently refractive-index-matched to the substrate. For this purpose, a polycarbonate is particularly suitable for the film and in particular the matrix material.

Polycarbonates have a refractive index of approximately 1.59. This material is refractive-index-matched well to a glass substrate, in particular a Borofloat glass substrate having a refractive index of approximately 1.54.

As an alternative or supplementarily, a refractive index matching material, for instance an optical gel, can also be arranged between the substrate 4 and the scattering film 8. Ideally, in the case where the scattering film is fixed to the component by means of an adhesion promoting layer 9, the adhesion promoting layer is embodied for refractive index matching. For this purpose, the adhesion promoter preferably has a refractive index that lies by no more than 20%, preferably no more than 10%, outside an interval delimited by the refractive indices of the substrate 4 and of the film material or of the matrix material. The refractive index matching material preferably has a refractive index lying between that of the substrate and that of the scattering film or of the film matrix.

By means of the refractive index matching, wave guiding in the substrate in the direction of the substrate lateral areas, which occurs to an increased extent for example in the case of a substrate-air interface, can be reduced.

Films that are particularly suitable for a component according to the invention, in particular a visible-light-emitting component, are described below.

Acrylates, in particular core-shell acrylates, can be used for transparent scattering particles ((scattering) pigments) of the scattering film. Said acrylates preferably have a sufficiently high thermal stability, e.g. up to at least 300° C., so as not to be decomposed at the processing temperatures of the transparent plastic, preferably polycarbonate.

Furthermore, the scattering pigments are intended to have no functionalities which lead to a degradation of the polymer chain of the polycarbonate. Thus, e.g. Paraloid® from Röhm & Haas or Techpolymer® from Sekisui can be used well for the pigmentation of transparent plastics. A multiplicity of different types are available from these product lines. Core-shell acrylates from the Techpolymer series are preferably used.

The film preferably has, in particular on the structured side that is to be remote from the component, a degree of gloss (measured according to EN ISO 2813 (angle 60°)) of less than 50%, preferably less than 40%, and/or of more than 0.5%. A roughness (measured according to ISO 4288) on the structured side is advantageously greater than 3 μm, preferably greater than 4 μm and/or less than 300 μm. preferably less than 50 μm.

On account of the brightness properties and simultaneously high light scattering, films of this type are particularly well suited to OLEDs.

The degree of gloss of the film surface is particularly important and influences the optical properties of the film. In particular, the optical impression of the non-operated component can be set by this means.

The film is preferably embodied as a plastic film comprising at least one layer. At least one layer of the film contains transparent polymeric particles having a refractive index that differs from that of the matrix material. The layer contains 50 to 99.99% by weight, preferably 70 to 99.99% by weight, of a transparent plastic, in particular polycarbonate, and 0.01 to 50% by weight, preferably 0.01 to 30% by weight, of polymeric particles. The particles preferably have an average particle size of essentially between 1 and 100 μm, preferably between 1 and 50 μm.

The film furthermore preferably has at least one structured side, the surface of the structured side having a degree of gloss (measured according to EN ISO 2813 (angle 60°)) of less than 50%, preferably less than 40%, and of more than 0.5% and a roughness (measured according to ISO 4288) of greater than 3 μm, preferably greater than 4 μm, and less than 50 μm, preferably less than 300 μm, on the structured side.

In a further configuration, the scattering film can also have a glossy surface. The latter is expediently embodied in unstructured fashion. In this case, the glossy surface is preferably formed by means of that surface of the scattering film which faces the component. Said surface preferably has a degree of gloss of more than 50%.

For the production of the structured film surfaces, preferably heated rubber rolls are used, as are disclosed in DE 32 28 002 (or the US equivalent U.S. Pat. No. 4,368,240) from Nauta Roll Corporation.

The film is furthermore preferably produced by thermoplastic processing.

The film surfaces are preferably structured with the aid of rolls, particularly preferably 3 rolls of a smoothing calender. The structures of the two rolls forming the roll nip, into which the melt (so-called melt curtain) enters after leaving the extruder die, are particularly crucial for the fashioning of the film surface. Silicone rubber coated rolls, as are disclosed, e.g. in U.S. Pat. No. 4,368,240 in the name of Nauta Roll Corporation, are preferably used for producing matt and/or structured film surfaces. Essential process engineering parameters for the impression of the structures are the temperature of the rubber roll and the pressure in the roll nip that is exerted on the melt curtain between the rolls. The process parameters can be rapidly determined by simple experiments.

By means of the combination of elevated temperature, e.g. 130° C., and a narrow relative roll nip, e.g. 0.6, it is possible to produce for example films composed of polycarbonate which have a pronounced structure.

A smooth and/or glossy surface is preferably produced by means of polished metal rolls. The film preferably has a thickness of 25 μm, preferably 30 μm, to 1000 μm. The film can also be a multilayer composite composed of at least two films.

Said composite can be produced by extrusion. As an alternative, separately prefabricated films can be arranged one on top of another and be connected to one another (so-called lining or laminating).

In order to produce a film by extrusion, the plastic granules, for example the polycarbonate granules, are fed to a filling funnel of an extruder and pass via this into the plasticizing system comprising screw and cylinder.

The plastic material is conveyed and melted in the plasticizing system. The plastic melt is forced through a slot die. A filter device, a melt pump, stationary mixing elements and further components can be arranged between plasticizing system and slot die. The melt leaving the die passes onto a smoothing calender. A rubber roll can be used for structuring the film surface on one side. The final shaping is effected in the roll nip of the smoothing calender. The rubber rolls preferably used for the structuring of the film surface are described in U.S. Pat. No. 4,368,240. Shape fixing ultimately takes place as a result of cooling, to be precise reciprocally on the smoothing rolls and at the ambient air. The further devices of the plasticizing system serve for transport, possibly desired application of protective films, and winding up the extruded films

All transparent thermoplastics can be used as plastics for the films: polyacrylates, polymethyl methacrylates (PMMA; Plexiglas® from Röhm), cycloolefin copolymers (COC; Topas® from Ticona); Zenoex® from Nippon Zeon or Apel® from Japan Synthetic Rubber), polysulphones (Ultrason® from BASF or Udel® from Solvay), polyesters, such as e.g. PET or PEN, polycarbonate, polycarbonate/polyester blends, e.g. PC/PET, polycarbonate/polycyclohexylmethanol cyclohexane dicarboxylate (PCCD; Xylecs® from GE) and polycarbonate/polybutylene terephthalate (PBT) blends.

A polycarbonate is preferably used. As already explained above, said polycarbonate is particularly suitable for the refractive index matching to an OLED.

Suitable polycarbonates for producing the film are all known polycarbonates. These are homopolycarbonates, copolycarbonates and thermoplastic polyester carbonates.

A suitable polycarbonate preferably has an average molecular weight M̅_{w} of 18 000 to 40 000, preferably of 26 000 to 36 000, and in particular of 28 000 to 35 000, determined by measuring the relative solution viscosity in dichloromethane or in mixtures of equal amounts by weight of phenol/o-dichlorobenzene calibrated by light scattering.

The production of the polycarbonates is preferably effected according to the interfacial method or the melt transesterification method and is described below by way of example on the basis of the interfacial method.

The polycarbonates are produced according to the interfacial method, inter alia. This method for polycarbonate synthesis is widely described in the literature: by way of example, reference should be made to H. Schnell, Chemistry and Physics of Polycarbonates, Polymer Reviews, Vol. 9, Inter-Science Publishers, New York 1964, page 33 et seq., to Polymer Reviews, Vol. 10, “Condensation Polymers by Interfacial and Solution Methods”, Paul W. Morgan, Interscience Publishers, New York 1965, Chapter VIII, page 325, to Dres. U. Grigo, K. Kircher and P. R. Müller “Polycarbonate” [“Polycarbonates”] in Becker/Braun, Kunstoff-Handburch [Plastics Handbook], Volume 3/1, Polycarbonate, Polyacetale, Polyester, Cellulose-ester [Polycarbonates, Polyacetals, Polyesters/Cellulose esters], Carl Hanser Verlag Munich, Vienna, 1992, pages 118-145, and also to EP-A 0 517 044.

Suitable diphenols are described e.g. in U.S. Pat. Nos. 2,999,835, 3,148,172, 2,991,273, 3,271,367, 4,982,014 and 2,999,846, in the published German Patent Applications 1 570 703, 2 063 050, 2 036 052, 2 211 956 and 3 832 396, French Patent 1 561 518, in the Monograph “H. Schnell, Chemistry and Physics of Polycarbonates, Interscience Publishers, New York 1964, page 28 et seq.; page 102 et seq.” and in “D. G. Legrand, J. T. Bendler, Handbook of Polycarbonate Science and Technology, Marcel Dekker New York 2000, page 72 et seq.”.

The production of polycarbonates is also possible from diaryl carbonates and diphenols according to the known polycarbonate method in the melt, the so-called melt transesterification method, which is described e.g. in WO-A 01/05866 and WO-A 01/05867. Moreover, transesterification methods (acetate methods and phenyl ester methods) are described for example in U.S. Pat. Nos. 3,494,885, 4,386,186, 4,661,580, 4,680,371 and 4,680,372, in EP-A 26 120, 26 121, 26 684, 28 030, 39 845, 91 602, 97 970, 79 075, 14 68 87, 15 61 03, 23 49 13 and 24 03 01 and also in DE-A 14 95 626 and 22 32 977.

Both homopolycarbonates and copolycarbonates are suitable. In order to produce copolycarbonates, it is also possible to use 1 to 25% by weight, preferably 2.5 to 25% by weight (based on the total amount of diphenols to be used), of polydiorganosiloxanes with hydroxy-aryloxy end groups. These are known (see for example from U.S. Pat. No. 3,419,634) or can be produced according to methods known in the literature. The production of polydiorganosiloxane-containing copoly-carbonates is described e.g. in DE-A 33 34 782.

Polyester carbonates and block copolyester carbonates, as described e.g. in WO 2000/26275, are furthermore suitable. Aromatic dicarbonyl dihalides for producing aromatic polyester carbonates are preferably the diacid dichlorides of isophthalic acid, terephthalic acid, diphenyl ether 4,4′-dicarboxylic acid and naphthalene-2,6-dicarboxylic acid.

The aromatic polyester carbonates can either be linear or have branching in a known manner (in this respect, also see DE-A 29 40 024 and DE-A 30 07 934).

The polydiorganosiloxane-polycarbonate block polymers can also be a mixture of polydiorganosiloxane-polycarbonate block copolymers with customary polysiloxane-free thermoplastic polycarbonates, where the total content of polydiorganosiloxane structural units in said mixture is approximately 2.5 to 25% by weight.

Polydiorganosiloxane-polycarbonate block copolymers of this type are known e.g. from U.S. Pat. No. 3,189,622, U.S. Pat. No. 3,821,325 and U.S. Pat. No. 3,832,419.

Preferred polydiorganosiloxane-polycarbonate block copolymers are produced by reacting polydiorganosiloxanes containing alpha, omega-bishydroxyaryloxy end groups together with other diphenols, if appropriate with concomitant use of branching agents in the customary amounts, e.g. according to the interfacial method (in this respect see H. Schnell, Chemistry and Physics of Polycarbonates Polymer Rev. Vol. IX, page 27 et seq., Interscience Publishers New York 1964), where the ratio of the bifunctional phenolic reactants is in each case chosen so as to result in a suitable content of aromatic carbonate structural units and diorganosiloxy units.

Such polydiorganosiloxanes containing alpha, omega-bishydroxyaryloxy end groups are known e.g. from U.S. Pat. No. 3,419,634.

As acrylate-based polymeric particles for scattering particles, use is preferably made of those as disclosed in EP-A 634 445.

The polymeric particles have a core composed of a rubber-like vinyl polymer. The rubber-like vinyl polymer can be a homopolymer or copolymer of any one of the monomers which have at least one ethylenically unsaturated group and which undergo an addition polymerization—as is generally known—under the conditions of emulsion polymerization in an aqueous medium. Such monomers are listed in U.S. Pat. No. 4,226,752, column 3, lines 40-62.

Most preferably, the polymeric particles contain a core composed of rubber-like alkyl acrylate polymer, the alkyl group having 2 to 8 carbon atoms, optionally copolymerized with 0 to 5% crosslinker and 0 to 5% graft crosslinker, based on the total weight of the core. The rubber-like alkyl acrylate is preferably copolymerized with up to 50% of one or more copolymerizable vinyl monomers, for example those mentioned above. Suitable crosslinking and graft-crosslinking monomers are described for example in EP-A 0 269 324.

The polymeric particles contain one or a plurality of shells. This one shell or this plurality of shells is or are preferably produced from a vinyl homopolymer or vinyl copolymer. Suitable monomers for producing the shell/shells are listed in U.S. Pat. No. 4,226,752, column 4, lines 20-46, reference being made to the indications with respect thereto. A shell or a plurality of shells is or are preferably a polymer composed of a methacrylate, acrylate, vinylarene, vinyl carboxylate, acrylic acid and/or methacrylic acid.

The polymeric particles are useful for imparting light scattering properties to the transparent plastic, preferably polycarbonate.

The polymeric particles preferably have an average particle diameter (mean particle diameter or size) of at least 0.5 micrometer, preferably of at least 1 micrometer to at most 100 micrometers, more preferably of 2 to 50 micrometers, most preferably of 2 to 30 micrometers. “Average particle diameter” (mean particle diameter) should be understood as the number average. Preferably at least 90%, most preferably at least 95%, of the polymeric particles have a diameter of more than 1 micrometer and less than 100 μm. The polymeric particles are preferably a free-flowing powder, preferably in compacted form.

The polymeric particles can be produced as follows: in general at least one monomer component of the core polymer is subjected to the emulsion polymerization with the formation of emulsion polymer particles. The emulsion polymer particles are swelled with the same or one or more other monomer components of the core polymer, and the monomer/monomers is/are polymerized within the emulsion polymer particles. The stages of swelling and polymerization can be repeated until the particles have grown to the desired core size. The core polymer particles are suspended in a second aqueous monomer emulsion, and a polymer shell composed of the monomer/monomers is polymerized onto the polymer particles in the second emulsion. One shell or a plurality of shells can be polymerized on the core polymer. The production of core/shell polymer particles is described in EP-A 0 269 324 and in U.S. Pat. Nos. 3,793,402 and 3,808,180.

The film is preferably produced by extrusion.

For extrusion purposes, polycarbonate granules are fed to the extruder and melted in the plasticizing system of the extruder. The plastic melt is forced through a slot die and deformed in the process, brought to the desired final shape in the roil nip of a smoothing calender and shape-fixed by reciprocal cooling on smoothing rolls and ambient air. The polycarbonates having high melt viscosity which are used for the extrusion are usually processed at melt temperatures of 260 to 320° C.; the cylinder temperatures of the plasticizing cylinder and also die temperatures are set correspondingly.

By using one or a plurality of side extruders and suitable melt adapters before the slot die, it is possible for polycarbonate melts of different compositions to be laid one above another and thus to produce multilayered films (see, for example, EP-A 0 110 221 and EP-A 0 110 238).

Both the base layer, in particular the layer with the scattering particles, and the optionally present coextrusion layer(s) of the films according to the invention can additionally contain additives, such as, for example, UV absorbers and/or other processing aids. This encompasses in particular mould release agents, flow agents, stabilizers customary for polycarbonates, in particular thermostabilizers, antistatic agents and/or optical brighteners. In this case, different additives or different concentrations of additives may be present in each layer. Preferably, the coextrusion layer(s) contains (contain) the antistatic agents, UV absorbers and/or mould release agents.

In a preferred embodiment, the composition of the film additionally contains 0.01 to 0.5% by weight of a UV absorber from the classes of benzotriazole derivatives, dimeric benzotriazole derivatives, triazine derivatives, dimeric triazine derivatives, diaryl cyanoacrylates.

Suitable stabilizers are, for example, phosphines, phosphites or Si containing stabilizers and further compounds described in EP-A 0 500 496. Mention shall be made by way of example of triphenyl phosphites, diphenyl alkyl phosphites, phenyl dialkyl phosphites, tris(nonylphenyl)phosphite, tetrakis(2,4-di-tert-butylphenyl) 4,4′-diphenylenediphosphonite, bis(2,4-dicumylphenyl)pentaerythritol diphosphite and triaryl phosphite. Triphenyl phosphine and tris(2,4-di-tert-butylphenyl)phosphite are particularly preferred.

Suitable mould release agents are for example the esters or partial esters of mono- to hexahydric alcohols, in particular of glycerol, of pentaerythritol or of Guerbet alcohols.

Monohydric alcohols are for example stearyl alcohol, palmityl alcohol and Guerbet alcohols, a dihydric alcohol is for example glycol, a trihydric alcohol is for example glycerol, tetrahydric alcohols are for example pentaerythritol and mesoerythritol, pentahydric alcohols are for example arabitol, ribitol and xylitol, and hexahydric alcohols are for example mannitol, glucitol(sorbitol) and dulcitol.

The esters are preferably the monoesters, diesters, triesters, tetraesters, pentaesters and hexaesters or their mixtures, in particular statistical mixtures, of saturated, aliphatic C₁₀ to C₃₆-monocarboxylic acids and, if appropriate, hydroxymonocarboxylic acids, preferably with saturated, aliphatic C₁₄ to C₃₂-monocarboxylic acids and, if appropriate, hydroxymonocarboxylic acids.

The commercially available fatty acid esters, in particular of pentaerythritol and of glycerol, can contain less than 60% of different partial esters due to production.

Saturated, aliphatic monocarboxylic acids having 10 to 36 carbon atoms are for example capric acid, lauric acid, myristic acid, palmitic acid, stearic acid, hydroxystearic acid, arachinic acid, behenic acid, lignoceric acid, cerotinic acid and montanic acids.

Examples of suitable antistatic agents are cationic compounds, for example quaternary ammonium, phosphonium or sulphonium salts, anionic compounds, for example alkylsulphonates, alkyl sulphates, alkyl phosphates, carboxylates in the form of alkali or alkaline earth metal salts, non-ionic compounds, for example polyethylene glycol esters, polyethylene glycol ethers, fatty acid esters, ethoxylated fatty amines. Preferred antistatic agents are quaternary ammonium compounds, such as e.g. dimethyldiisopropylammonium perfluorobutanesulphonate.

The production of the film is explained in more detail on the basis of the following example.

### Example

A) Production of a Masterbatch by Compounding:

The masterbatch is produced by means of conventional twin-screw compounding extruders (e.g. ZSK 32) at processing temperatures of 250 to 330° C. that are customary for polycarbonate.

A masterbatch having the following composition was produced:
1. 80% by weight of Makrolon® 3108 550115 (polycarbonate (PC) from Bayer MaterialScience AG)
2. 20% by weight of core-shell particles with a butadiene/styrene core and a methyl methacrylate shell (Techpolymerφ MBX 5 from Sekisui) having a particle size of 2 to 15 μm and an average particle size of 8 μm.

The apparatus used for producing the films comprises
1. a main extruder having a screw of 105 mm diameter (D) and a length of 41×D; the screw has a devolatilization zone;
2. a three-roll smoothing calender with horizontal roll arrangement, the third roll being pivotable by ±45° with respect to the horizontal;
3. a roller track;
4. a device for applying protective film on both sides;
5. a take-off device;
6. winding-up station.

The granules of the light-scattering material were supplied to the filling funnel of the main extruder. The material was melted and conveyed in the plasticizing system cylinder/screw of the extruder. The material melt was fed to the smoothing calender, the rolls of which were at the temperature stated in the table below. The final shaping and cooling of the film took place on the smoothing calender (comprising three rolls). In this case, a rubber roll was used for structuring the film surface on one side. The rubber roll used for structuring the film surface is disclosed in U.S. Pat. No. 4,368,240 in the name of Nauta Roll Corporation. The film was subsequently transported through a take-off. Afterwards, a protective film composed of PE can be applied on both sides and the film can be wound up.

| TABLE | |
|---|---|
| Process parameters | |
| Temperature of the main extruder | approximately 275° C. |
| Temperature of the deflection head | approximately 285° C. |
| Temperature of the die | approximately 300° C. |
| Rotational speed of the main extruder | 45 min⁻¹ |
| Temperature of the rubber roll 1 | 24° C. |
| Temperature of the roll 2 | 72° C. |
| Temperature of the roll 3 | 131° C. |
| Take-off rate | 21.5 m/min |

### Example

The following light-scattering composition was fed to the main extruder:
1. 50.0% by weight of Makrolon® 3108 550115 (PC from Bayer MaterialScience AG)
2. 50.0% by weight of masterbatch (as described above under A)).

An extrusion film of a light-scattering layer with a structured surface and a total thickness of 300 μm was obtained from this.

The scattering properties of the scattering film can be described reliably and in a particularly simple manner by means of the Henyey-Greenstein phase function P

$$P ( cos ϑ ) = \frac{1 - {g}^{2}}{4 {π ( 1 + {g}^{2} - 2 g cos ϑ )}^{\frac{3}{2}}}$$

In this case, θ is the intermediate angle between a beam incident on the scattering film and said beam after scattering. For a transmission scattering film, θ is formed between the (imaginary) continuation of the incident beam on the exit side and the emerging beam.

The scattering anisotrophy factor g (g factor) describes the scattering properties of the scattering film. Said g factor lies between −1 and 1, where a value of −1 corresponds to specular backscattering, a value of 0 corresponds to isotropic scattering and a value of 1 corresponds to no change in the beam course. g factors in the range greater than 0 specify the forward scattering. The g factor is accessible experimentally.

The relationship between the intensity distribution I(Θ) before scattering and the intensity distribution I′(Θ′) after scattering by the film is given by the relationship

I′(Θ′)=P(cos θ)·I(Θ)

In this case, Θ and Θ′ designate the angle of the incident radiation and, respectively, the angle of the scattered radiation relative to the respective normal to the surface, where θ is determined by the difference between said angles.

The suitable selection of a scattering film which is admixed with scattering particles and preferably has a scattering structure at a film surface can have a considerable influence on the maximum obtainable increase for the radiation power coupled out from the component in relation to a corresponding component without a scattering film.

It goes without saying that component-internal parameters, such as the absorption in the component, also influence the coupling-out efficiency. However, component-internal parameters can no longer readily be changed after the component has been completed. In contrast to this, however, the scattering film 8 can be subsequently fixed to the component 1. In the case of a scattering film that is subsequently provided, the production process for the components can advantageously be carried out without altered process parameters.

In a preferred configuration, the scattering film 8, in particular with regard to the component, is formed in such a way that the g factor lies between 0.3 and 0.9 inclusive, particularly preferably between 0.5 and 0.7 inclusive.

FIG. 4 graphically illustrates the results of a simulation calculation in this regard. In this case, various g factors were assumed for the scattering film. The dependence of the increase in coupled-out radiation power on the proportion of scattering particles of a predetermined type in per cent by weight for a scattering film having a predetermined thickness was determined. For the various g factors, the increase has a pronounced maximum in each case. The scattering film is expediently formed for a predetermined component in such a way that the increase lies near or at the maximum.

It has been found that an increase of more than 20% can be obtained by means of a scattering film having a g factor of between 0.3 and 0.9 inclusive. A film having a g factor of between 0.5 and 0.7 inclusive is preferably used since particularly high increases—above 30% and in particular up to above 40%—can be obtained in this case.

FIG. 5 shows measurement results for the dependence of the increase in coupled-out radiation power on the number of scattering particles in the volume per unit area in a plan view of the film for scattering particles of a predetermined type and, if appropriate, a predetermined scattering structure of the film. For various proportions of scattering particles in per cent by weight (wt. %), the absolute number of particles in the volume per unit area in a plan view of the film in a film can in each case be chosen in such a way that the increase is in the region of the maximum achievable increase or the increase is equal to the maximum achievable increase. In particular, the frequency of scattering events in the film can be varied by means of the number of particles. When determining the dependence of the increase on the number of particles in the volume per unit area in a plan view of the film, the thickness of the scattering film can be varied for a predetermined particle size (distribution). For the scattering film, the particle number density in the film is expediently formed in such a way that the increase is optimal.

FIG. 6 shows the dependence of the increase in coupled-out radiation power on the viewing angle for an OLED that was provided with a 300 μm thick polymer scattering film as coupling-out layer.

In this case, the viewing angle was measured relative to the normal to the surface of the coupling-out area of the scattering film. A white-light-emitting component was used as organic radiation-emitting component. In the angle range measured, the increase always lies above twenty per cent and has a maximum at approximately 43 per cent. The average increase is approximately 35 per cent.

Despite the increased coupling-out, the component with the scattering film has an essentially unchanged emission characteristic by comparison with a corresponding component without a scattering film. In both components—with and without film—the emission characteristic at least in the range between 0° and 70° essentially corresponds to that of a Lambertian emitter and therefore has a cosinusoidal profile (cf. FIG. 7).

Besides the increased coupling-out and the specific light emission that is homogeneous on the coupling-out side, a further advantage of the scattering film is that fluctuations in the colour locus can be compensated for via the coupling-out side of the component. The colour locus can change in particular with the viewing angle. Colour locus fluctuations of this type are intrinsically present in many OLEDs. Colour locus fluctuations, that is to say fluctuations in the x and/or y coordinates in accordance with the CIE (Commission Internationale l'Eclairage), can be reduced by means of the scattering film (cf. FIG. 8).

Furthermore, small defect regions, i.e. dark regions in which a considerably reduced luminous flux couples out from the component, can be “covered up” by means of the diffusive scattering film.

FIGS. 9A and 9B illustrate, for OLEDs having different radiation-generating polymers, the increases obtained by means of the scattering film at different operating currents I for two components of different types. OLEDs having visible-light-emitting polymers were used in each case. A material that emits in the yellow spectral range was investigated in FIG. 9A and a white-light-emitting material was investigated in FIG. 9B.

Particularly high increases were obtained in the case of the white light source, which is particularly advantageous for illumination applications with white light.

At the different operating currents, the specific light emission in lm/(m²) was measured in each case with and without a scattering film for otherwise identical components (columns: max., min. and centre). Under the respective measured values, the respective increase relative to the comparison component is indicated in per cent. The individual columns specify the maximum (max.) and minimum (min.) specific light emission and the specific light emission in the central region of the coupling-out area (centre) and also the average specific light emission and the corresponding increase.

The invention is not restricted by the description on the basis of the exemplary embodiments. Rather, the invention encompasses any new feature and also any combination of features, which in particular comprises any combination of features in the patent claims, even if this feature or this combination itself is not explicitly specified in the patent claims or exemplary embodiments.

1. A component comprising:
an organic radiation-emitting element having an organic layer formed for generating radiations;
a radiation coupling-out side; and
a scattering film arranged on the radiation coupling-out side of the element and being connected to the element.

2. The component according to claim 1, comprising a substrate, on which the organic layer is arranged, the scattering film being arranged on that side of the substrate which is remote from the organic layer and being connected to the substrate.

3. The component according to claim 1, wherein,
the scattering film is formed as a transmission scattering film which scatters radiation passing through the scattering film during operation of the component.

4. The component according to claim 1, wherein,
the scattering film comprises a film matrix admixed with scattering particles.

5. The component according to claim 4, wherein scattering particles are formed such that they are radiation-transmissive.

6. The component according to claim 4, wherein the scattering particles comprise organic particles.

7. The component according to claim 4, wherein the scattering particles comprise hollow particles.

8. The component according to claim 4, wherein the scattering particles comprise particles with a core-shell construction.

9. The component according to claim 4, wherein the scattering particles have an average particle diameter of between 0.5 micrometer and 50 micrometers inclusive, preferably between 2 micrometers and 30 micrometers inclusive.

10. The component according to claim 1, wherein a scattering structure is formed in a surface of the scattering film.

11. The component according to claim 10,
wherein the scattering film comprises a film matrix admixed with scattering particles.

12. The component according to claim 1, wherein the scattering film or the film matrix contains a plastic that is transmissive to the radiation generated in the component.

13. The component according to claim 12, wherein the plastic is a polycarbonate.

14. The component according to claim 1, wherein the scattering film or the film matrix is refractive-index-matched to the element.

15. The component according to claim 13, wherein the substrate contains glass.

16. The component according to claim 1, wherein the scattering film is fixed to the element by means of an adhesion promoter, or in which the scattering film is laminated onto the element.

17. The component according to claim 1, wherein the substrate is formed from a fragmentable material, and the scattering film is formed in mechanically stable fashion and connected to the substrate in such a way that a fragmented substrate is held together by means of the scattering film.

18. The component according to claim 1, wherein the scattering film has a thickness of between 1 μm and 1 mm inclusive.

19. The component according to claim 1, wherein an ultraviolet-radiation-absorbing element is connected to the organic radiation-emitting element.

20. The component according to claim 19, wherein the ultraviolet-radiation-absorbing element is arranged on that side of the substrate which is remote from the organic layer.

21. The component according to claim 19, wherein the element is a separate UV protective film.

22. The component according to claim 19, wherein the scattering film is formed such that it is UV-absorbent.

23. The component according to claim 1, wherein the scattering film is formed in antistatic fashion.

24. The component according to claim 1, wherein is formed as an organic light-emitting diode.

25. The component according to claim 1, wherein the element is adapted for lighting.

26. Use of a film for a coupling-out layer for an organic radiation-emitting component.
